(19) United States
(12) Patent Application Publication
(10) Pub. No.: US 2014/0264688 A1
(43) Pub. Date: Sep. 18, 2014

(54) SOLID STATE IMAGING DEVICE AND METHOD FOR MANUFACTURING THE SAME

(71) Applicant: Kabushiki Kaisha Toshiba, Minato-ku (JP)

(72) Inventor: Nobuki KANREI, Kanagawa-ken (JP)

(73) Assignee: Kabushiki Kaisha Toshiba, Minato-ku (JP)

(21) Appl. No.: 14/023,593

(22) Filed: Sep. 11, 2013

(30) Foreign Application Priority Data
Mar. 12, 2013 (JP) 2013-049703

(51) Int. Cl. H01L 27/146

(52) U.S. Cl. CPC H01L 27/14627; H01L 27/14685
USPC 257/432; 438/70

(57) ABSTRACT

According to one embodiment, a solid state imaging device includes a silicon substrate unit, a color filter layer, first, second and third optical layers. The silicon substrate unit includes imaging units provided in a plane parallel to a major surface. The color filter layer is apart from the silicon substrate unit. The color filter has a lower refractive index than the silicon substrate unit. The first optical layer has a lower first refractive index than the color filter layer and the silicon substrate unit, and is light transmissive. The second optical layer has a second refractive index higher than the first refractive index and lower than the refractive index of the silicon substrate unit, is light transmissive. The third optical layer has a third refractive index lower than the refractive index of the color filter layer and lower than the second refractive index, and is light transmissive.

### CROSS-REFERENCE TO RELATED APPLICATIONS

This application is based upon and claims the benefit of priority from Japanese Patent Application No. 2013-049703, filed on Mar. 12, 2013; the entire contents of which are incorporated herein by reference.

### FIELD

Embodiments described herein relate generally to a solid state imaging device and a method for manufacturing the same.

### BACKGROUND

In a solid state imaging device such as a CMOS image sensor and a CCD image sensor, there is a configuration in which a layer that adjusts the refractive index to suppress reflection is provided between an imaging unit and a color filter layer in order to improve sensitivity, for example. Obtaining stable characteristics is required as well as improving sensitivity.

### BRIEF DESCRIPTION OF THE DRAWINGS

FIG. 1 is a schematic cross-sectional view illustrating a solid state imaging device according to a first embodiment;

FIG. 2 is a schematic plan view illustrating the solid state imaging device according to the first embodiment;

FIGS. 3 to 5 are graphs illustrating characteristics of the solid state imaging device;

FIG. 6 is a flow chart illustrating a method for manufacturing a solid state imaging device according to a second embodiment;

FIG. 7 is a flow chart illustrating another method for manufacturing a solid state imaging device according to the second embodiment;

FIG. 8 is a flow chart illustrating another method for manufacturing the solid state imaging device according to the second embodiment; and

FIG. 9 is a flow chart illustrating another method for manufacturing the solid state imaging device according to the second embodiment.

### DETAILED DESCRIPTION

According to one embodiment, a solid state imaging device includes a silicon substrate unit, a color filter layer, a first optical layer, a second optical layer and a third optical layer. The silicon substrate unit includes a plurality of imaging units provided in a plane parallel to a major surface. The color filter layer is apart from the silicon substrate unit in a direction perpendicular to the major surface. The color filter has a refractive index lower than a refractive index of the silicon substrate unit. The first optical layer is provided between the silicon substrate unit and the color filter layer. The first optical layer has a first refractive index lower than the refractive index of the color filter layer and lower than the refractive index of the silicon substrate unit, and is light transmissive. The second optical layer is provided between the first optical layer and the color filter layer. The second optical layer has a second refractive index higher than the first refractive index and lower than the refractive index of the silicon substrate unit, is light transmissive, and is a polycrystal. The third optical layer is provided between the second optical layer and the color filter layer. The third optical layer has a third refractive index lower than the refractive index of the color filter layer and lower than the second refractive index, and is light transmissive.

According to one embodiment, a method for manufacturing a solid state imaging device is disclosed. The method can include forming a stacked body on a silicon substrate unit including a plurality of imaging units provided in a plane parallel to a major surface. The stacked body includes a first optical layer, a second optical layer, and a third optical layer. The first optical layer has a first refractive index lower than a refractive index of the silicon substrate unit and is light transmissive. The second optical layer is provided on the first optical layer, has a second refractive index higher than the first refractive index and lower than the refractive index of the silicon substrate unit, is light transmissive, and is a polycrystal. The third optical layer is provided on the second optical layer, has a third refractive index lower than the second refractive index, and is light transmissive. In addition, the method can include forming a color filter layer on the stacked body. The color filter layer has a refractive index higher than the first refractive index and higher than the third refractive index.

Various embodiments will be described hereinafter with reference to the accompanying drawings.

The drawings are schematic or conceptual; and the relationships between the thickness and width of portions, the proportions of sizes among portions, etc. are not necessarily the same as the actual values thereof. Further, the dimensions and proportions may be illustrated differently among drawings, even for identical portions.

In the specification of this application and the drawings, components similar to those described in regard to a drawing thereinabove are marked with the same reference numerals, and a detailed description is omitted as appropriate.

### First Embodiment

FIG. 1 is a schematic cross-sectional view illustrating a solid state imaging device according to a first embodiment.

As shown in FIG. 1, a solid state imaging device 110 according to the embodiment includes a silicon substrate unit 10, a color filter layer 50, a first optical layer 31, a second optical layer 32, and a third optical layer 33. In this example, the solid state imaging device 110 is a back-side illumination imaging device. In the back-side illumination imaging device, light is incident from the back surface side of the silicon substrate unit 10. The solid state imaging device 110 is a CMOS image sensor, for example.

The silicon substrate unit 10 has a major surface 10a. One surface (e.g. upper surface) of the silicon substrate unit 10 may be taken as the major surface 10a, for example.

The direction perpendicular to the major surface 10a is defined as the Z-axis direction. One direction perpendicular to the Z-axis direction is defined as the X-axis direction. The direction perpendicular to the Z-axis direction and the X-axis direction is defined as the Y-axis direction.

The silicon substrate unit 10 includes a plurality of imaging units 12. The plurality of imaging units 12 are provided in the X-Y plane (a plane parallel to the major surface 10a). In this example, the silicon substrate unit 10 includes a silicon layer 13 and the plurality of imaging units 12 provided in part of the silicon layer 13. The silicon layer 13 is a p-type semiconductor layer, for example. The imaging unit 12 is a photodiode including a pn junction, for example. The silicon substrate unit 10 further includes a CMOS circuit unit 11. The imaging unit 12 is provided in contact with the CMOS circuit unit 11 in the silicon substrate unit 10, for example.

In this example, the silicon substrate unit 10 is provided on a support substrate 5. The CMOS circuit unit 11 is provided between the support substrate 5 and the imaging unit 12 and between the support substrate 5 and the silicon layer 13.

In the specification of this application, the state of being “provided on” includes the state of being provided in direct contact and the state of being provided via another component.

The color filter layer 50 is apart from the silicon substrate unit 10 in the Z-axis direction (the direction perpendicular to the major surface 10a). The color filter layer 50 has a refractive index lower than the refractive index of the silicon substrate unit 10.

The refractive index of the silicon substrate unit 10 at the wavelength of 530 nanometers (nm) is not less than 4.2 and not more than 4.3, for example. The refractive index of the color filter layer 50 at the wavelength of 530 nanometers is not less than 1.55 and not more than 1.65, for example. An acrylic resin is used for the color filter layer 50, for example.

The first optical layer 31 is provided between the silicon substrate unit 10 and the color filter layer 50. The first optical layer 31 has a first refractive index lower than the refractive index of the color filter layer 50 and lower than the refractive index of the silicon substrate unit 10. The first optical layer 31 is light transmissive.

The second optical layer 32 is provided between the first optical layer 31 and the color filter layer 50. The second optical layer 32 has a second refractive index higher than the first refractive index and lower than the refractive index of the silicon substrate unit 10. The second optical layer 32 is light transmissive, and is a polycrystal.

The third optical layer 33 is provided between the second optical layer 32 and the color filter layer 50. The third optical layer 33 has a third refractive index lower than the refractive index of the color filter layer 50 and lower than the second refractive index. The third optical layer 33 is light transmissive.

That is, in this example, the first optical layer 31, the second optical layer 32, and the third optical layer 33 are provided in this order on the silicon substrate unit 10. A stacked body 30s including the first optical layer 31, the second optical layer 32, and the third optical layer 33 functions as a reflection suppression layer, for example.

In this example, a planarization layer 40 is provided between the third optical layer 33 and the color filter layer 50. The planarization layer 40 is provided as necessary and may be omitted.

The color filter layer 50 includes a first color layer 51a, a second color layer 51b, and a third color layer 51c. The first color layer 51a is red, for example. The second color layer 51b is green, for example. The third color layer 51c is blue, for example. These color layers are arranged in the X-Y plane. When projected onto the X-Y plane, each of these color layers overlaps with each of the plurality of imaging units 12.

In this example, a plurality of condensing lenses (a first lens 53a, a second lens 53b, and a third lens 53c) are provided. The first color layer 51a is disposed between the first lens 53a and one imaging unit 12. The second color layer 51b is disposed between the second lens 53b and one imaging unit 12. The third color layer 51c is disposed between the third lens 53c and one imaging unit 12.

In this example, a planarization film 52 is provided between the condensing lenses and the color filter layer 50. The planarization film 52 is light transmissive. The planarization film 52 is provided as necessary and may be omitted.

One imaging unit 12 corresponds to one sub-pixel (a first sub-pixel 81a, a second sub-pixel 81b, and a third sub-pixel 81c).

In the solid state imaging device 110, one pixel 80 includes the first sub-pixel 81a, the second sub-pixel 81b, and the third sub-pixel 81c, for example. Such a pixel 80 is provided in plural in the X-Y plane. FIG. 1 illustrates one of the plurality of pixels 80 provided in the solid state imaging device 110.

FIG. 2 is a schematic plan view illustrating the solid state imaging device according to the first embodiment.

As shown in FIG. 2, a plurality of pixels 80 are arranged in the silicon substrate unit 10. In addition, a plurality of vertical scan lines 85, a vertical scanning circuit 85a, a plurality of horizontal scan lines 86, a horizontal scanning circuit 86a, a signal processing circuit 87, and an output amplifier 88 are provided.

Each of the plurality of vertical scan lines 85 extends in the X-axis direction, for example. Each of the plurality of horizontal scan lines 86 extends in the Y-axis direction, for example. Each of the plurality of imaging units 12 is disposed at each of the intersections of these scan lines.

The plurality of vertical scan lines 85 are connected to the vertical scanning circuit 85a. The plurality of horizontal scan lines 86 are connected to the horizontal scanning circuit 86a via the signal processing circuit 87. Light is incident on the pixel 80 (the imaging unit 12), and the characteristics of the pixel change. An electric signal reflecting the change of the characteristics of the pixel 80 in accordance with the intensity of light is inputted to the output amplifier 88 via the signal processing circuit 87 and the horizontal scanning circuit 86a. An electric signal corresponding to imaging data is outputted from the output amplifier 88.

In the solid state imaging device 110 according to the embodiment, the first optical layer 31, the second optical layer 32, and the third optical layer 33 are provided between the silicon substrate unit 10 and the color filter layer 50, which have refractive indices greatly different from each other.

The thicknesses of these optical layers are set thinner than the wavelengths of visible light, for example. The thickness of the first optical layer 31, the thickness of the second optical layer 32, and the thickness of the third optical layer 33 are thinner than 380 nm, for example.

The thickness of the first optical layer 31 is not less than 10 nm and less than 25 nm, for example, and is approximately 15 nm, for example. The thickness of the second optical layer 32 is not less than 25 nm and less than 50 nm, and is 35 nm, for example. The thickness of the third optical layer 33 is not less than 10 nm and not more than 200 nm, and is 15 nm, for example.

The second refractive index of the second optical layer 32 is set to a value between the first refractive index of the first optical layer 31 and the third refractive index of the third optical layer 33.

The first refractive index at the wavelength of 530 nm is not less than 1.45 and less than 1.55, for example. The second refractive index at the wavelength of 530 nm is not less than 2.55 and not more than 2.66. The third refractive index at the wavelength of 530 nm is not less than 1.45 and less than 1.55.

Polycrystalline titanium oxide (e.g. TiO₂) is used for the second optical layer 32, for example, and a refractive index of not less than 2.55 and not more than 2.66 is obtained.

The second optical layer 32 suppresses reflection loss by being provided between the silicon substrate unit 10 with a high refractive index and the color filter layer 50 with a low refractive index. The second refractive index of the second optical layer 32 is set to a value near the square root (approximately 2.6) of the product of the refractive index of the silicon substrate unit 10 (approximately 4.25) and the refractive index of the color filter layer 50 (approximately 1.6). Thereby, reflection loss can be reduced. The second refractive index at the wavelength of 530 nm is set not less than 2.55 and not more than 2.66 as mentioned above, for example. Thereby, reflection in the visible light range can be effectively suppressed. Thus, high sensitivity imaging is enabled.

The first optical layer 31 functions as an underlayer for the second optical layer 32. The second optical layer 32 protects the first optical layer 31, for example. The third optical layer 33 functions as a cap layer for the second optical layer 32, and the third optical layer 33 protects the second optical layer 32.

Silicon oxide is used for the first optical layer 31 and the third optical layer 33, for example. The first refractive index of the first optical layer 31 and the third refractive index of the third optical layer 33 at the wavelength of 530 nm are approximately 1.46.

In the solid state imaging device 110 according to the embodiment, a polycrystalline layer is used as the second optical layer 32. Thereby, the stability of characteristics is enhanced. It has been found that when an amorphous layer is used as the second optical layer 32, characteristics are less likely to be stabilized, for example.

The denseness of the amorphous layer is low, for example. Hence, gas, a chemical liquid, an impurity, etc. are likely to enter the layer. In addition, in an amorphous titanium oxide layer, the state is likely to change, for example. Due to a process after the formation of the second optical layer 32, heat may be applied to the second optical layer 32, for example. If amorphous titanium oxide is used as the second optical layer 32, the state of the titanium oxide layer changes and optical characteristics change due to the heat.

In contrast, the denseness of the polycrystalline layer is high. Hence, the entry of gas, a chemical liquid, an impurity, etc. into the layer can be suppressed. Thereby, stable characteristics are obtained. In addition, crystallized titanium oxide does not turn into an amorphous state. Even when heat is applied to polycrystalline titanium oxide, it does not turn into an amorphous state, for example. Thus, by using a polycrystalline layer as the second optical layer 32, the variation in characteristics when and immediately after the solid state imaging device is manufactured can be suppressed, and reliability in use can be improved.

The embodiment can provide a solid state imaging device with high stability and high sensitivity.

As described later, when titanium oxide is used as the second optical layer 32, polycrystalline titanium oxide provides a higher refractive index than amorphous titanium oxide.

In the case where the second optical layer 32 is used as a reflection suppression layer, the thickness and the refractive index of the second optical layer 32 are set so that the optical film thickness is a prescribed value. At this time, by using polycrystalline titanium oxide with a high refractive index, the thickness of the second optical layer 32 can be made thinner than when amorphous titanium oxide with a low refractive index is used. Since the thickness can be made thin, the crosstalk between pixels can be suppressed, and imaging of high image quality is enabled.

By using polycrystalline titanium oxide, a refractive index of not less than 2.55 and not more than 2.66, which is a desired value, is obtained.

Characteristics of a titanium oxide layer in the case where titanium oxide is used as the second optical layer 32 will now be described.

FIG. 3 is a graph illustrating characteristics of the solid state imaging device.

FIG. 3 is XRD characteristics showing characteristics of titanium oxide films formed under various conditions on a silicon oxide film provided on a silicon substrate.

A first sample SP01 is a sample in which a titanium oxide layer is formed by sputtering using a target of titanium oxide and no heat treatment is performed. A second sample SP350 is a sample in which a titanium oxide layer formed by sputtering is heat-treated at 350° C. A third sample SP400 is a sample in which a titanium oxide layer formed by sputtering is heat-treated at 400° C. A fourth sample SP450 is a sample in which a titanium oxide layer formed by sputtering is heat-treated at 450° C. A fifth sample SP550 is a sample in which a titanium oxide layer formed by sputtering is heat-treated at 550° C. The horizontal axis of FIG. 3 is the rotation angle 2θ (degrees), and the vertical axis is the detected intensity (an arbitrary unit).

As can be seen from FIG. 3, in the first sample SP01 in which no heat treatment is performed, no clear peak is observed. The oxide titanium layer is amorphous in the first sample SP01.

In contrast, in the first to fourth samples in which heat treatment is performed, a peak is observed at a rotation angle 2θ of approximately 25.3 degrees. This shows that a crystal of the anatase structure exists in these samples. The crystal is oriented in the (101) plane.

That is, by forming a titanium oxide layer by sputtering and performing heat treatment (e.g. 350° C. or more), a titanium oxide layer having crystallinity of the anatase structure is obtained.

FIG. 4 is a graph illustrating characteristics of the solid state imaging device.

FIG. 4 is XRD characteristics showing characteristics of titanium oxide films formed under various conditions on a silicon oxide film provided on a silicon substrate.

A sixth sample SQ01 is a sample in which a titanium layer is formed by sputtering using a target of titanium (metal) and no thermal oxidation treatment is performed. A seventh sample SQ380 is a sample in which a titanium layer formed by sputtering undergoes thermal oxidation treatment at 380° C. for 1 hour. An eighth sample SQ421 is a sample in which a titanium layer formed by sputtering undergoes thermal oxidation treatment at 420° C. for 1 hour. A ninth sample SQ422 is a sample in which a titanium layer formed by sputtering undergoes thermal oxidation treatment at 420° C. for 3 hours. The horizontal axis of FIG. 4 represents the rotation angle 2θ (degrees), and the vertical axis represents the detected intensity (an arbitrary unit).

As can be seen from FIG. 4, in the sixth sample SQ01 in which no thermal oxidation treatment is performed, no clear peak is observed.

In contrast, in the seventh to ninth samples in which thermal oxidation treatment is performed, a peak is observed at rotation angles 2θ of approximately 27.5 degrees and approximately 36.5 degrees. The peak at the rotation angle 2θ of approximately 27.5 degrees corresponds to a titanium oxide layer of the rutile structure with the (110) plane orientation. The peak at the rotation angle 2θ of approximately 36.5 degrees corresponds to a titanium oxide layer of the rutile structure with the (101) plane orientation.

Thus, by forming a titanium layer by sputtering and performing thermal oxidation treatment, a titanium oxide layer having crystallinity of the rutile structure is obtained.

As can be seen from FIG. 3 and FIG. 4, a crystal of the rutile structure is substantially not mixed in a crystal of the anatase structure. On the other hand, a crystal of the anatase structure is substantially not mixed in a crystal of the rutile structure. Thus, a single kind of crystal structure is obtained in these samples.

A large number of structural defects exist in an amorphous titanium oxide layer, for example. The number of structural defects is small in a titanium oxide layer of the anatase structure. The number of structural defects is still smaller in titanium oxide of the rutile structure.

The denseness is significantly low in an amorphous titanium oxide layer. High denseness is obtained in a titanium oxide layer of the anatase structure. The denseness is further improved in titanium oxide of the rutile structure.

The refractive index of the amorphous titanium oxide layer is approximately not less than 2.45 and not more than 2.52 at the wavelength of 530 nm, for example. In the titanium oxide layer of the anatase structure, a refractive index of not less than approximately 2.55 and not more than approximately 2.6 is obtained. In the titanium oxide of the rutile structure, a refractive index of not less than approximately 2.61 and not more than approximately 2.67 is obtained and the refractive index is still higher.

It is preferable to use titanium oxide of the rutile structure in terms of structural defects being few, the denseness being high, and the refractive index being high. On the other hand, in a titanium oxide layer of the anatase structure, the manufacturing is easy, and uniform, stable characteristics with high repeatability are easily obtained.

FIG. 5 is a graph illustrating characteristics of the solid state imaging device.

FIG. 5 illustrates simulation results of the reflectance at wavelengths from 400 nm to 700 nm when the thickness t3 of the third optical layer 33 is changed from 0 nm to 30 nm. In the simulation, the wavelength dispersion of the refractive index of the silicon substrate unit 10 is considered. The refractive index at the wavelength of 530 nm of the silicon substrate unit 10 is 4.3. The refractive index at the wavelength of 530 nm of the color filter layer 50 is 1.6. The first optical layer 31 is in contact with the silicon substrate unit 10. The refractive index at the wavelength of 530 nm of the first optical layer 31 is 1.46. The thickness of the first optical layer 31 is 15 nm. The refractive index at the wavelength of 530 nm of the second optical layer 32 is 2.6. The thickness of the second optical layer 32 is 35 nm. The third optical layer 33 is in contact with the color filter layer 50, and the refractive index at the wavelength of 530 nm of the third optical layer 33 is 1.46. The horizontal axis of FIG. 5 is the wavelength λ (nm). The vertical axis is the reflectance Rf (%). In FIG. 5, the case where the thickness t3 is 0 nm corresponds to the case where the third optical layer 33 is not provided.

As can be seen from FIG. 5, changing the thickness t3 of the third optical layer 33 has little influence on the optical film thickness; thus, the reflectance at near the desired wavelength of 530 nm hardly changes. In the embodiment, the thickness of the third optical layer 33 is set to approximately 15 nm, for example. Thereby, the reflectance in a wavelength range from 400 nm to 700 nm is approximately 4.5% on average, and the reflectance Rf can be made low in a relatively wide wavelength range.

### Second Embodiment

A second embodiment relates to a method for manufacturing a solid state imaging device.

FIG. 6 is a flow chart illustrating a method for manufacturing a solid state imaging device according to the second embodiment.

As shown in FIG. 6, in the manufacturing method, the stacked body 30s is formed on the silicon substrate unit 10 including a plurality of imaging units 12 provided in a plane parallel to the major surface 10a (the X-Y plane) (step S110). The stacked body 30s includes the first optical layer 31, the second optical layer 32, and the third optical layer 33. The first optical layer 31 has the first refractive index lower than the refractive index of the silicon substrate unit 10, and is light transmissive. The second optical layer 32 is provided on the first optical layer 31, has the second refractive index higher than the first refractive index and lower than the refractive index of the silicon substrate unit 10, is light transmissive, and is a polycrystal. The third optical layer 33 is provided on the second optical layer 32, has the third refractive index lower than the second refractive index, and is light transmissive.

In the manufacturing method, the color filter layer 50 is formed on the stacked body 30s (step S120). The refractive index of the color filter layer 50 is higher than the first refractive index and higher than the third refractive index, for example.

The embodiment can provide a method for manufacturing a solid state imaging device with high stability and high sensitivity.

In the embodiment, titanium oxide is used for the second optical layer 32. The titanium oxide is a polycrystal, and has the anatase structure or the rutile structure.

An example of the manufacturing method will now be described.

FIG. 7 is a flow chart illustrating another method for manufacturing the solid state imaging device according to the second embodiment.

As shown in FIG. 7, in this example, the first optical layer 31 is formed (step S111) in the formation of the stacked body 30s (step S110). An amorphous titanium oxide film is formed on the first optical layer 31 (step S112). The titanium oxide film is formed by sputtering, for example.

The amorphous titanium oxide film is heat-treated to be polycrystallized to form the second optical layer 32 (step S113). The heat treatment is performed at a temperature of 350° C. or more, for example. The heat treatment is performed at a temperature of 550° C. or less, for example.

The third optical layer 33 is formed on the second optical layer 32 (step S114).

Thereby, the second optical layer 32 of titanium oxide having the anatase structure is obtained.

FIG. 8 is a flow chart illustrating another method for manufacturing the solid state imaging device according to the second embodiment.

As shown in FIG. 8, in this example, the first optical layer 31 is formed (step S111) in the formation of the stacked body 30s (step S110). An amorphous titanium oxide film is formed on the first optical layer 31 (step S112). Also in this case, the titanium oxide film is formed by sputtering, for example.

The third optical layer 33 is formed on the amorphous titanium oxide film while heated, and the amorphous titanium oxide film is polycrystallized to form the second optical layer 32 (step S114a). In the formation of the third optical layer 33 while performing heating, the temperature of heating is 350 degrees or more, for example. By forming the third optical layer 33 while performing heating, the amorphous titanium oxide film is polycrystallized, and a polycrystalline titanium oxide layer is obtained.

Thereby, the second optical layer 32 of titanium oxide having the anatase structure is obtained.

In the methods illustrated in FIG. 7 and FIG. 8, it has been found that when the heating of the substrate is performed in the formation of the amorphous titanium oxide film (step S112), a layer in which the anatase structure and the rutile structure are mixed is likely to be formed. In such a layer in which the crystal structures are mixed, the flatness of the surface is not good, and the unevenness of the surface is large. Thus, in the formation of the amorphous titanium oxide film, it is preferable to perform no active heating of the substrate. When the amorphous titanium oxide film is formed by sputtering, the temperature of the substrate may be increased due to the sputtering. The amorphous titanium oxide film is obtained under the conditions where no active heating is performed. The temperature of the substrate when the amorphous titanium oxide film is formed is 60° C. or less, for example. Thereby, the amorphous titanium oxide film is obtained, and subsequently polycrystallization is performed to obtain a polycrystal of a single kind of crystal structure.

FIG. 9 is a flow chart illustrating another method for manufacturing the solid state imaging device according to the second embodiment.

As shown in FIG. 9, in this example, the first optical layer 31 is formed (step S111) in the formation of the stacked body 30s (step S110). In this example, a silicon oxide layer is used as the first optical layer 31 and the third optical layer 33.

A titanium layer (a titanium layer of metal) is formed on the first optical layer 31 (step S112a). The titanium layer is formed by the sputtering method, for example.

The titanium layer is thermally oxidized to form polycrystalline titanium oxide to form the second optical layer 32 (step S113a).

The third optical layer 33 is formed on the second optical layer 32 (step S114).

Thereby, the second optical layer 32 of titanium oxide having the rutile structure is obtained.

It has been found that when a titanium layer is formed and the titanium layer is thermally oxidized to obtain polycrystalline titanium oxide in this way, the film quality of the titanium layer greatly influences the film quality of the titanium oxide layer.

When the titanium layer has columnar grain boundaries, the crystal in the titanium oxide layer after oxidation is likely to be non-uniform. When the titanium layer has granular grain boundaries, it is easy to obtain a uniform, dense polycrystal in the titanium oxide layer after oxidation. The granular grain boundary includes a grain boundary in a curved surface form, for example. It has been found that when the diameter of each granular grain boundary in the titanium layer is not less than 5 nm and not more than 20 nm, the titanium oxide layer after oxidation forms a dense polycrystal of the rutile structure, and a uniform high refractive index is obtained.

Such a titanium layer can be formed by the sputtering method using a target of titanium. At this time, the pressure in the sputtering film formation (for example, the pressure of argon gas) is set relatively large, and the power is adjusted; thereby, it becomes easy to obtain granular grain boundaries like the above.

If the in-film oxygen concentration in the titanium layer formed by sputtering is excessively high, it is difficult to obtain a uniform polycrystal. The in-film oxygen concentration in the titanium layer is preferably 20 atomic percent or less.

The embodiment can provide a solid state imaging device with high stability and high sensitivity and a method for manufacturing the same.

Hereinabove, embodiments of the invention are described with reference to specific examples. However, the embodiment of the invention is not limited to these specific examples. For example, one skilled in the art may appropriately select specific configurations of components of solid state imaging devices such as imaging units, silicon substrates, optical layers, planarization layers, planarization films, color filter layers, and condensing lenses from known art and similarly practice the invention. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all solid imaging devices and methods for manufacturing the same practicable by an appropriate design modification by one skilled in the art based on the slid imaging devices described and the methods for manufacturing the same above as embodiments of the invention also are within the scope of the invention to the extent that the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solid state imaging device comprising:
a silicon substrate unit including a plurality of imaging units provided in a plane parallel to a major surface;
a color filter layer apart from the silicon substrate unit in a direction perpendicular to the major surface, the color filter having a refractive index lower than a refractive index of the silicon substrate unit;
a first optical layer provided between the silicon substrate unit and the color filter layer, the first optical layer having a first refractive index lower than the refractive index of the color filter layer and lower than the refractive index of the silicon substrate unit, and being light transmissive;
a second optical layer provided between the first optical layer and the color filter layer, the second optical layer having a second refractive index higher than the first refractive index and lower than the refractive index of the silicon substrate unit, being light transmissive, and being a polycrystal; and
a third optical layer provided between the second optical layer and the color filter layer, the third optical layer having a third refractive index lower than the refractive index of the color filter layer and lower than the second refractive index, and being light transmissive.

2. The device according to claim 1, wherein
the first optical layer and the third optical layer include silicon oxide and
the second optical layer includes titanium oxide.

3. The device according to claim 1, wherein
a thickness of the first optical layer is thinner than 380 nm,
a thickness of the second optical layer is thinner than 380 nm, and
a thickness of the third optical layer is thinner than 380 nm.

4. The device according to claim 1, wherein
a thickness of the first optical layer is not less than 10 nanometers and less than 25 nanometers,
a thickness of the second optical layer is not less than 25 nanometers and less than 50 nanometers, and
a thickness of the third optical layer is not less than 10 nanometers and not more than 200 nanometers.

5. The device according to claim 1, wherein the second refractive index at a wavelength of 530 nanometers is not less than 2.55 and not more than 2.66.

6. The device according to claim 5, wherein
the first refractive index at a wavelength of 530 nanometers is not less than 1.45 and less than 1.55 and
the third refractive index at a wavelength of 530 nanometers is not less than 1.45 and less than 1.55.

7. The device according to claim 1, wherein the second refractive index at a wavelength of 530 nanometers is not less than 2.61 and not more than 2.67.

8. The device according to claim 7, wherein
the first refractive index at a wavelength of 530 nanometers is not less than 1.45 and less than 1.55 and
the third refractive index at a wavelength of 530 nanometers is not less than 1.45 and less than 1.55.

9. The device according to claim 1, wherein
the second optical layer includes polycrystalline titanium oxide and
the first optical layer and the third optical layer include silicon oxide.

10. The device according to claim 1, wherein the second optical layer includes titanium oxide of an anatase structure.

11. The device according to claim 1, wherein the second optical layer includes titanium oxide of a rutile structure.

12. A method for manufacturing a solid state imaging device comprising:
forming a stacked body on a silicon substrate unit including a plurality of imaging units provided in a plane parallel to a major surface, the stacked body including a first optical layer, a second optical layer, and a third optical layer, the first optical layer having a first refractive index lower than a refractive index of the silicon substrate unit and being light transmissive, the second optical layer being provided on the first optical layer, having a second refractive index higher than the first refractive index and lower than the refractive index of the silicon substrate unit, being light transmissive, and being a polycrystal, the third optical layer being provided on the second optical layer, having a third refractive index lower than the second refractive index, and being light transmissive; and
forming a color filter layer on the stacked body, the color filter layer having a refractive index higher than the first refractive index and higher than the third refractive index.

13. The method according to claim 12, wherein
the second optical layer is a titanium oxide layer and
the forming the stacked body includes
after forming an amorphous titanium oxide film on the first optical layer, polycrystallizing the amorphous titanium oxide film by heat treatment to form the second optical layer, and forming the third optical layer on the second optical layer or forming the third optical layer on the amorphous titanium oxide film while performing heating and polycrystallizing the amorphous titanium oxide film to form the second optical layer.

14. The method according to claim 13, wherein a temperature of the heat treatment is not less than 350° C. and not more than 550° C.

15. The method according to claim 12, wherein
the first optical layer and the third optical layer are a silicon oxide layer,
the second optical layer is a titanium oxide layer, and
the forming the stacked body includes
forming a titanium layer including a granular grain boundary on the first optical layer,
thermally oxidizing the titanium layer to form polycrystalline titanium oxide to form the second optical layer, and
forming the third optical layer on the second optical layer.

16. The method according to claim 15, wherein a diameter of the granular grain boundary is not less than 5 nanometers and not more than 20 nanometers.

17. The method according to claim 15, wherein the granular grain boundary has a grain boundary in a curved surface form.

18. The method according to claim 15, wherein an in-film oxygen concentration in the titanium layer is 20 atomic percents or less.

19. The method according to claim 12, wherein the second optical layer includes titanium oxide of an anatase structure.

20. The method according to claim 12, wherein the second optical layer includes titanium oxide of a rutile structure.
